(19) United States
(12) Patent Application Publication
(10) Pub. No.: US 2014/0027712 A1
(43) Pub. Date: Jan. 30, 2014

(54) DEVICES INCLUDING QUANTUM DOTS AND METHOD

(71) Applicant: QD Vision, Inc., Lexington, MA (US)

(72) Inventor: Craig Breen, Somerville, MA (US)

(73) Assignee: QD Vision, Inc., Lexington, MA (US)

(21) Appl. No.: 14/041,881

(22) Filed: Sep. 30, 2013

Related U.S. Application Data
(63) Continuation of application No. PCT/US2012/023671, filed on Feb. 2, 2012.
(60) Provisional application No. 61/471,135, filed on Apr. 2, 2011.

(51) Int. Cl. H01L 33/06

(52) U.S. Cl. CPC H01L 33/06
USPC 257/13; 438/22

(57) ABSTRACT

A method for preparing a device, the method comprising: forming a first device layer over a first electrode, the layer comprising a metal oxide formed from a sol-gel composition that does not generate acidic by-products, and forming a second electrode over the first device layer, wherein the method further includes forming a layer comprising quantum dots over the first electrode before or after formation of the first device layer. Also disclosed is a device comprising a first device layer formed over a first electrode, the first device layer comprising a metal oxide formed by sol-gel processing that does not include acidic by-products, a second electrode over the first device layer, and a layer comprising quantum dots disposed between the first device layer and one of the two electrodes. A device prepared by the method is also disclosed.

This application is a continuation of commonly owned International Application No. PCT/US2012/023671 filed 2 Feb. 2012, which published in the English language as PCT Publication No. WO 2012/138409 on 11 Oct. 2012, which International Application claims priority to U.S. Application No. 61/471,135 filed 2 Apr. 2011. Each of the foregoing is hereby incorporated herein by reference in its entirety.

### FEDERALLY SPONSORED RESEARCH OR DEVELOPMENT

This invention was made with Government support under Advanced Technology Program Award No. 70NANB7H7056 awarded by NIST. The United States has certain rights in the invention.

### TECHNICAL FIELD OF THE INVENTION

The present invention relates to the technical field of devices including quantum dots.

### SUMMARY OF THE INVENTION

In accordance with one aspect of the present invention there is provided a method for preparing a device, the method comprising:

forming a first device layer over a first electrode, the layer comprising a metal oxide formed from a sol-gel composition that does not generate acidic by-products, and

forming a second electrode over the first device layer,

wherein the method further includes forming a layer comprising quantum dots over the first electrode before or after formation of the first device layer.

Preferred metal oxides for inclusion in the first device layer comprise zinc oxide, titanium oxide, and mixtures thereof.

The first device layer can comprise a charge transport layer. For example, the first device layer may comprise a material capable of transporting electrons (also referred to herein as an electron transport layer). The first device layer can comprise a material capable of transporting electrons and injecting electrons (also referred to herein as an electron transport and injection layer). The first layer can comprise a material capable of transporting holes (also referred to herein as a hold transport layer).

The method can further include forming a second device layer (e.g., a second charge transport layer). The second layer is preferably formed such that the layer comprising quantum dots is disposed between the first and second device layers.

Advantageously, the present method includes formation of a first device layer from a sol-gel composition that avoids formation of acidic by-products which are believed to be detrimental to the device preparation and/or operation.

One of the electrodes may be formed on a substrate on which the device is built.

The method optionally further comprises formation of other optional layers, including, for example, but not limited to, charge blocking layers, charge injecting layers, etc., in the device.

The device can comprise a light-emitting device wherein the layer comprising quantum dots comprises an emissive material.

In accordance with another aspect of the present invention, there is provided a device prepared by the method taught herein.

In accordance with a further aspect of the present invention there is provided a device comprising a first device layer formed over a first electrode, the first device layer comprising a metal oxide formed by sol-gel processing that does not include acidic by-products, a second electrode over the first device layer, and a layer comprising quantum dots disposed between the first device layer and one of the two electrodes.

Preferred metal oxides for inclusion in the first device layer comprise zinc oxide, titanium oxide, and mixtures thereof.

The first device layer can comprise a charge transport layer. For example, the first device layer may comprise a material capable of transporting electrons (also referred to herein as an electron transport layer). The first device layer can comprise a material capable of transporting electrons and injecting electrons (also referred to herein as an electron transport and injection layer). The first layer can comprise a material capable of transporting holes (also referred to herein as a hold transport layer).

The device can further include a second device layer (e.g., a charge transport layer) such that the layer comprising quantum dots is disposed between the first and second device layers.

The device may further include a substrate. For example, the first or second electrode may be formed on a substrate.

The substrate may be selected from: glass, plastic, quartz, metal foil, silicon wafer (doped or undoped). Other substrate materials may be used.

The device method can further comprise other optional layers, including, for example, but not limited to, charge blocking layers, charge injecting layers, etc., in the device.

The device can comprise a light-emitting device wherein the layer comprising quantum dots comprises an emissive material.

The foregoing, and other aspects described herein, all constitute embodiments of the present invention.

It should be appreciated by those persons having ordinary skill in the art(s) to which the present invention relates that any of the features described herein in respect of any particular aspect and/or embodiment of the present invention can be combined with one or more of any of the other features of any other aspects and/or embodiments of the present invention described herein, with modifications as appropriate to ensure compatibility of the combinations. Such combinations are considered to be part of the present invention contemplated by this disclosure.

It is to be understood that both the foregoing general description and the following detailed description are exemplary and explanatory only and are not restrictive of the invention as claimed.

Other embodiments will be apparent to those skilled in the art from consideration of the description and drawings, from the claims, and from practice of the invention disclosed herein.

### BRIEF DESCRIPTION OF THE DRAWINGS

In the drawings:

FIGS. 1A and 1B depict examples of various device structures in accordance with the invention.

FIG. 2 depicts an example of a device structure in accordance with the invention.

FIG. 3 depicts an example of a device structure in accordance with the invention.

The attached figures are simplified representations presented for purposes of illustration only; actual structures may differ in numerous respects, including, e.g., relative scale, etc.

For a better understanding to the present invention, together with other advantages and capabilities thereof, reference is made to the following disclosure and appended claims in connection with the above-described drawings.

### DETAILED DESCRIPTION OF THE INVENTION

Various aspects and embodiments of the present inventions will be further described in the following detailed description.

In accordance with one aspect of the present invention there is provided a method for preparing a device, the method comprising:

forming a first device layer over a first electrode, the layer comprising a metal oxide formed from a sol-gel composition that does not generate acidic by-products, and

forming a second electrode over the first device layer,

wherein the method further includes forming a layer comprising quantum dots over the first electrode before or after formation of the first device layer.

Preferred metal oxides for inclusion in the first device layer comprise zinc oxide, titanium oxide, and mixtures thereof.

The first device layer can comprise a charge transport layer. For example, the first device layer may comprise a material capable of transporting electrons (also referred to herein as an electron transport layer). The first device layer can comprise a material capable of transporting electrons and injecting electrons (also referred to herein as an electron transport and injection layer). The first layer can comprise a material capable of transporting holes (also referred to herein as a hold transport layer).

The method can further include forming a second device layer (e.g., a second charge transport layer) before or after formation of the layer comprising quantum dots, such that the layer comprising quantum dots is disposed between the first and second device layers.

Advantageously, the present method includes formation of a first device layer from a sol-gel composition that avoids formation of acidic by-products which are believed to be detrimental to the device preparation and/or operation. Such acidic by-products can, for example, quench quantum dot emission and/or react with ligands on the quantum dots, which can adversely affect quantum dot performance

One of the electrodes may be formed on a substrate on which the device is built.

The substrate may be selected from: glass, plastic, quartz, metal foil, silicon wafer (doped or undoped). Other substrate materials may be used.

The method optionally further comprises formation of other optional layers, including, for example, but not limited to, charge blocking layers, charge injecting layers, etc., in the device.

In certain embodiments, the first device layer may comprise an electron transport layer or a hole transport layer. In certain embodiments, an electron transport layer may also comprise an electron injection layer.

The device can comprise a light-emitting device wherein the layer comprising quantum dots comprises an emissive material.

In accordance with another aspect of the present invention, there is provided a device prepared by the method taught herein.

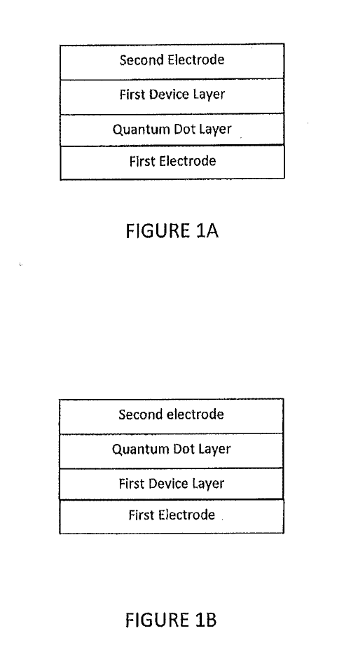

FIG. 1A depicts an example of device structure including a first electrode with a layer comprising quantum dots thereover, a first device layer disposed over the quantum dot layer, and a second electrode over the first device layer.

FIG. 1B depicts an example of a device structure including a first electrode with a first device layer, a layer comprising quantum dots disposed over the first device layer, and a second electrode over the first device layer.

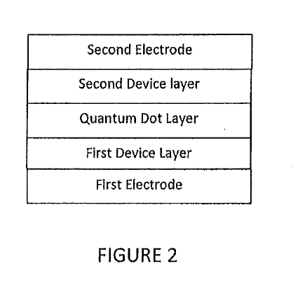

FIG. 2 depicts an example of a device structure including a first electrode with a first device layer, a layer comprising quantum dots disposed over the first device layer, a second layer over the quantum dot layer, and a second electrode over the second device layer.

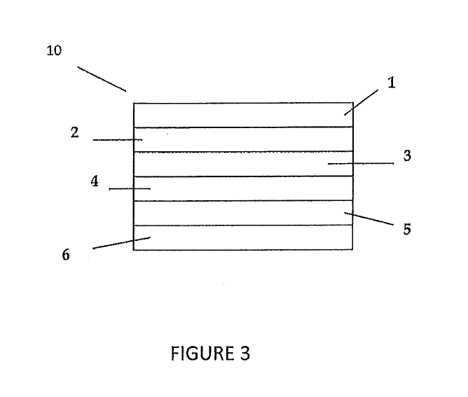

FIG. 3 provides a schematic representation of an example of one embodiment of another device structure in accordance with the present invention.

As described herein, any of the examples of the devices shown in any of FIGS. 1A, 1B, 2, and 3 can further include one or more additional device layers.

Optionally, in addition to the first device layer, any other device layer comprising a metal oxide can be formed from a sol-gel composition that does not generate acidic by-products.

In accordance with a further aspect of the present invention there is provided a device comprising a first device layer formed over a first electrode, the first device layer comprising a metal oxide formed by sol-gel processing that does not include acidic by-products, a second electrode over the first device layer, and a layer comprising quantum dots disposed between the first device layer and one of the two electrodes.

Preferred metal oxides for inclusion in the first device layer comprise zinc oxide, titanium oxide, and mixtures thereof.

The first device layer can comprise a charge transport layer. For example, the first device layer may comprise a material capable of transporting electrons (also referred to herein as an electron transport layer). The first device layer can comprise a material capable of transporting electrons and injecting electrons (also referred to herein as an electron transport and injection layer). The first layer can comprise a material capable of transporting holes (also referred to herein as a hold transport layer).

The device can further include a second device layer (e.g., a charge transport layer) such that the layer comprising quantum dots is disposed between the first and second device layers.

The device may further include a substrate. For example, the first or second electrode may be formed on a substrate.

The substrate may be selected from: glass, plastic, quartz, metal foil, silicon wafer (doped or undoped). Other substrate materials may be used.

The device method can further comprise other optional layers, including, for example, but not limited to, charge blocking layers, charge injecting layers, etc., in the device.

The device can comprise a light-emitting device wherein the layer comprising quantum dots comprises an emissive material.

One or more other layers in the device may further comprise a metal oxide that can be optionally also be prepared from a sol-gel composition that does not generate acidic by-products.

A first device layer can comprise a metal oxide. Examples of metal oxides that can be included in the first device layer include, for example, but are not limited to, zinc oxide, a titanium oxide, a niobium oxide, an indium tin oxide, copper oxide, nickel oxide, vanadium oxide, chromium oxide, indium oxide, tin oxide, gallium oxide, manganese oxide, iron oxide, cobalt oxide, aluminum oxide, thallium oxide, silicon oxide, germanium oxide, lead oxide, zirconium oxide, molybdenum oxide, hafnium oxide, tantalum oxide, tungsten oxide, cadmium oxide, iridium oxide, rhodium oxide, ruthenium oxide, osmium oxide. Other metal oxides may be determined to be useful or desirable.

A sol-gel composition in accordance with the present invention comprises a composition for producing a metal oxide that that does not generate acidic by-products.

For example, a sol-gel composition can comprise a metal oxide precursor. Examples of preferred metal oxide precursors include metal hydroxides, metal alkoxides, metal alkylalkoxides, and other metal oxide precursors that react to form a metal oxide without generating acidic by-products such as, for example, those formed from metal oxide precursors comprising metal salts (e.g., metal carboxylates, metal salts of oxyacids, metal halides, etc.).

Examples of metal oxide precursors for forming a zinc oxide layer in the present method include zinc hydroxide, zinc alkoxides (methoxide, ethoxide, isopropoxide, butoxide, etc.).

Examples of metal oxide precursors for forming a titanium oxide layer in the present method include titanium hydroxide, titanium alkoxides (methoxide, ethoxide, isopropoxide, butoxide, etc.).

In certain embodiments, the amount of metal oxide precursor in the sol-gel composition can be greater than about 0.5M, e.g., in a range from about 0.5 to 0.9, in a range from about 0.6 to about 0.8M, etc. In certain embodiments, the amount of metal oxide precursor in the sol-gel composition is about 0.7M. Other amounts outside this range may be determined to be useful or desirable.

A sol-gel composition typically further comprises a solvent.

Example of solvents includes alcohols, mixtures including one or more alcohols; water, preferably deionized water; and mixtures including water (preferably deionized water) and one or more alcohols. Examples of alcohols include, but are not limited to, an aliphatic alcohol having from 1-3 carbon atoms (e.g., methanol, ethanol, and/or propanols).

Other solvents may be determined to be useful or desirable.

A preferred solvent can be capable of dissolving the metal oxide precursor.

Solution processing to fabricate a first device layer described herein may comprise preparing a sol-gel composition by, for example, preparing a metal oxide precursor solution in a solvent, at room temperature and forming a layer thereof on a surface on which the layer is to be formed. Thereafter the layer is heated at a temperature sufficient to convert the metal oxide precursor to metal oxide. Preferably such temperature is less than 200° C. (e.g., preferably at 150° for forming zinc oxide) in air or other oxygen containing atmosphere for a period of time sufficient to convert zinc acetate to zinc oxide (e.g., 15-30 minutes at 150°). Solution processing is preferably carried out in air or other oxygen containing atmosphere.

A sol-gel composition may further include other optional known additives, such as a catalyst.

In certain embodiments, heating of the sol-gel composition is carried out for a period of time sufficient to obtain a meta-state with sufficient electron-transport ability.

An example of one of the methods for forming the layer of sol-gel composition can comprise spin coating (e.g., ranges from 1000 rpm to 3000 rpm, e.g., 2000 rpm). Other spin-coating rates may be determined to be useful or desirable.

As described above, the sol-gel layer can be formed by depositing the sol-gel composition onto the electrode or other layer of a device.

A first device layer can preferably have a thickness in a range from about 10 nm to 500 nm. Other thicknesses may be determined to be useful or desirable based on the particular device architecture and materials included in the device.

FIG. 3 provides a schematic representation of an example of one embodiment of a device in accordance with the present invention.

Referring to FIG. 3, the depicted example of a device 10 includes a structure (from top to bottom) including a first electrode 1 (e.g., a cathode), a first charge transport layer 2 formed form a sol-gel composition in accordance with the invention (e.g., a layer comprising a material capable of transporting electrons (as referred to herein as an “electron transport layer”), a layer comprising quantum dots 3, an optional second charge transport layer 4 (e.g., a layer comprising a material capable of transporting holes (also referred to herein as a “hole transport material”), a second electrode 5 (e.g., an anode), and a substrate 6. A charge injecting layer (e.g., PEDOT:PSS) (now shown) can be disposed for example, between the second electrode and second charge transport layer. When voltage is applied across the anode and cathode, the anode injects holes into the hole injecting material while the cathode injects electrons into the electron transport material. The injected holes and injected electrons combine to form an exciton on the quantum dots and emit light.

In an example of another embodiment of a device in accordance with the present invention, a device can include a structure which includes (from top to bottom) an anode, a first charge transport layer comprising a material capable of transporting holes (as referred to herein as an “hole transport layer”), a layer comprising quantum dots 3, a second charge transport layer comprising a material capable of transporting electrons (as referred to herein as an “electron transport layer”) formed form a sol-gel composition in accordance with the invention, a cathode), and a substrate 6. A hole injecting layer (e.g., PEDOT:PSS) (now shown) can be disposed for example, between the anode and first charge transport layer.

Examples of various substrates, other charge transport materials, hole injection materials, electrode materials, quantum dots (e.g., semiconductor nanocrystals), and other additional layers that may be optionally included in a device are described below.

The example of the device illustrated in FIG. 3 can be a light emitting device wherein the layer comprising quantum dots comprises an emissive material.

An example of a preferred light emitting device architecture is described in International Application No. PCT/US2009/002123, filed 3 Apr. 2009, by QD Vision, Inc., et al, entitled “Light-Emitting Device Including Quantum Dots”, which published as WO2009/123763 on 8 Oct. 2009, which is hereby incorporated herein by reference in its entirely.

Other multilayer structures may optionally be used (see, for example, U.S. patent application Ser. Nos. 10/400,907 (now U.S. Pat. No. 7,332,211) and 10/400,908 (now U.S. Pat. No. 7,700,200), filed Mar. 28, 2003, each of which is incorporated by reference in its entirety).

A first device layer taught herein can also be included in other types of electronic or optoelectronic devices. Examples of such devices include, but are not limited to, light-emitting devices, thin-film transistors, photodetectors, sensors, as well as photovoltaic cells.

A device layer comprising a metal oxide prepared as described herein may further comprise one or more additional sol-gel and/or non-sol-gel films. A non-sol-gel film may be organic, inorganic, hybrids, or mixtures thereof.

Examples of metal oxides include titanium oxide, zinc oxide, silicon oxide, etc. Other metal oxides may be determined to be useful or desirable for inclusion in a first device layer. A first device layer may also include a mixture of two or more metal oxides prepared as taught herein.

In certain preferred embodiments, the metal oxide comprises zinc oxide. An example of a metal oxide precursor for zinc oxide includes zinc hydroxide.

A substrate may be of a material such as, for example, glass, plastic, quartz, metal foil, silicon (doped or undoped) with and without other materials or layers on the substrate.

For example, a metal oxide formed from a sol-gel composition taught herein can be deposited onto a device layer (e.g., a layer comprising quantum dots, a charge transport layer, an electrode, etc.) that is formed directly or indirectly on a substrate (there may or may not be other materials or layers in between).

A first device layer may be formed in an ambient atmosphere and/or under different conditions. The different conditions may have oxygen molecules and/or other molecules as the environment gas.

In certain embodiments, a first device layer prepared in accordance with the present invention can provide a smooth solid state layer (preferably with a surface roughness (RMS) less than or equal to 1.5 nm, more preferably less than or equal to 1 nm, at a 500 nm scale)) at a low temperature (e.g., less than 200° C., less than 185° C., less than or equal to 150° C.). Such can be beneficial when underlying device layers (e.g., a quantum dot layer) and/or the performance thereof can be sensitive to higher temperatures.

Typically, the metal oxide precursor is converted to a metal oxide a temperature higher than ambient or room temperature.

A device in accordance with the invention can be fabricated, for example, by a method comprising forming a first device layer comprising a metal oxide by spin-coating a sol-gel composition that does not generate acidic by-products comprising a metal oxide precursor solution on top of already formed layer comprising quantum dots. For example, by baking in air at a temperature that would not harm the light-emitting performance of the quantum dots, a first device layer (e.g., a charge transport layer) described herein can be formed in situ. A layer of conductive contact composed of inactive metal (like Al, Ag, Au, e.g., by thermal decomposition) can be formed thereover or a layer of conductive metal oxides (like ITO, IZO etc.) can be formed thereover (e.g., by sputtering), as top contact, for the device.

For example, a first device layer can be prepared on top of a layer comprising quantum dots (QD Layer) in a partially fabricated device by spin-casting the sol-gel composition on the QD layer and baking same on a hotplate set at, e.g., 150° C., in air for about 30 min. (The partial device can further include a hole transport layer (e.g., TFB) under the QD layer and other device layers thereunder, such as, for example, those mentioned in the description of FIG. 3.) Following heating, the partial device can be moved into a vacuum oven in an inert-gas circulated glovebox to bake at a similar low temperature for another 30 min. Thereafter, in a thermal deposition chamber, a metal cathode contact can be formed thereover by either Ag or Al, or other metals; or a layer of conductive metal oxide is formed by sputtering; or by pasting certain cathode contact like Ag-paste. The device can thereafter preferably be encapsulated. For example, a device can be encapsulated by a cover glass with UV-curable epoxy.

A first device layer taught herein that is formed from a zinc oxide precursor can comprise a hybrid organic/inorganic electron transport/electron injecting layer in a device.

Depending on the selection of materials used to fabricate the device, such device can be top-emitting, bottom-emitting, or both (e.g., by choosing the transparency of the contact conductors and other device layers).

A first device layer described herein can be prepared by solution spin coating, casting, or printing under ambient conditions. Charge transport layers comprising a first device layer described herein can have application in commercial products such as, for example, backplanes for organic light emitting diodes, RFID tags, organic sensors, gas sensors, bio sensors, and ASICs.

The first electrode can be, for example, a cathode.

A cathode can comprise a low work function (e.g., less than 4.0 eV), electron-injecting, metal, such as Al, Ba, Yb, Ca, a lithium-aluminum alloy (Li:Al), a magnesium-silver alloy (Mg:Ag), or lithium fluoride—aluminum (LiF:Al). Other examples of cathode materials include silver, gold, ITO, etc. An electrode, such as Mg:Ag, can optionally be covered with an opaque protective metal layer, for example, a layer of Ag for protecting the cathode layer from atmospheric oxidation, or a relatively thin layer of substantially transparent ITO. An electrode can be sandwiched, sputtered, or evaporated onto the exposed surface of the solid layer.

In certain embodiments, the cathode can comprise silver.

The second electrode can be, for example, an anode.

An anode can comprise a high work function (e.g., greater than 4.0 eV) hole-injecting conductor, such as an indium tin oxide (ITO) layer. Other anode materials include other high work function hole-injection conductors including, but not limited to, for example, tungsten, nickel, cobalt, platinum, palladium and their alloys, gallium indium tin oxide, zinc indium tin oxide, titanium nitride, polyaniline, or other high work function hole-injection conducting polymers. An electrode can be light transmissive or transparent. In addition to ITO, examples of other light-transmissive electrode materials include conducting polymers, and other metal oxides, low or high work function metals, conducting epoxy resins, or carbon nanotubes/polymer blends or hybrids that are at least partially light transmissive. An example of a conducting polymer that can be used as an electrode material is poly(ethlyendioxythiophene), sold by Bayer AG under the trade mark PEDOT. Other molecularly altered poly(thiophenes) are also conducting and could be used, as well as emaraldine salt form of polyaniline.

In certain embodiments, the anode comprises aluminum.

One or both of the electrodes can be patterned.

The electrodes of the device can be connected to a voltage source by electrically conductive pathways.

A substrate can be opaque or transparent. A transparent substrate can be used, for example, in the manufacture of a transparent light emitting device. See, for example, Bulovic, V. et al., Nature 1996, 380, 29; and Gu, G. et al., Appl. Phys. Lett. 1996, 68, 2606-2608, each of which is incorporated by reference in its entirety. The substrate can be rigid or flexible. Examples of substrate materials include, without limitation, glass, plastic, metal, insulated metal foil, semiconductor wafer, etc. The substrate can be a substrate commonly used in the art. Preferably the substrate has a smooth surface. A substrate surface free of defects is particularly desirable.

Substrates including patterned ITO are commercially available and can be used in making a device according to the present invention.

In certain embodiments, the substrate comprises glass or silicon.

Other materials may be determined to be useful or desirable for fabrication or inclusion in the various layers in the device.

Other optional device layers (not shown) may also be included in the device. The particular device layers, materials included in each of the device layers, and the device structure are selected based on the type of device desired. For example, the materials and structures for various light emitting devices, photovoltaic devices, and other devices can be readily determined and carried out by one of ordinary skill in the relevant art. Such selection of materials and structure, and preparation thereof, can be readily determined and carried out by one of ordinary skill in the relevant art.

In certain embodiments, a layer may comprise more than one layer.

In certain embodiments, the device structure can be inverted.

Charge transport layers comprising organic materials and other information related to fabrication of organic charge transport layers are discussed in more detail in U.S. patent application Ser. No. 11/253,612 for “Method And System For Transferring A Patterned Material”, filed 21 Oct. 2005(U.S. Published Application No. 2006/0196375A1), U.S. patent application Ser. No. 11/253,595 for “Light Emitting Device Including Semiconductor Nanocrystals”, filed 21 Oct. 2005 (U.S. Published Application No. 2008/0001167A1), and International Application No. PCT/US2009/002123, filed 3 Apr. 2009, by QD Vision, Inc., et al, entitled “Light-Emitting Device Including Quantum Dots”, which published as WO2009/123763 on 8 Oct. 2009, the foregoing patent applications are hereby incorporated herein by reference in its entirety.

In certain embodiments, the hole transport layer comprises poly(9,9′-dioctylfluorene-co-N-(4-butylphenyl)diphenylamine (TFB).

Organic charge transport layers may be disposed by known methods such as a vacuum vapor deposition method, a sputtering method, a dip-coating method, a spin-coating method, a casting method, a bar-coating method, a roll-coating method, and other film deposition methods. Preferably, organic layers are deposited under ultra-high vacuum (e.g., ≦10⁻⁸ torr), high vacuum (e.g., from about 10⁻⁸ torr to about 10⁻⁵ torr), or low vacuum conditions (e.g., from about 10⁻⁵ torr to about 10⁻³ torr). Most preferably, the organic layers are deposited at high vacuum conditions from about 1×10⁻⁷ to about 5×10⁻⁶ torr. Alternatively, organic layers may be formed by multi-layer coating while appropriately selecting solvent for each layer.

Charge transport layers including inorganic materials and other information related to fabrication of inorganic charge transport layers are discussed further below and in more detail in U.S. Patent Application No. 60/653,094 for “Light Emitting Device Including Semiconductor Nanocrystals”, filed 16 Feb. 2005, U.S. patent application Ser. No. 11/354,185, filed 15 Feb. 2006 (U.S. Published Application No. 2007/0103068), and International Application No. PCT/US2009/002123, filed 3 Apr. 2009, by QD Vision, Inc., et al, entitled “Light-Emitting Device Including Quantum Dots”, which published as WO2009/123763 on 8 Oct. 2009, the disclosures of each of which are hereby incorporated herein by reference in their entireties.

Charge transport layers comprising an inorganic semiconductor can be deposited at a low temperature, for example, by a known method, such as a vacuum vapor deposition method, an ion-plating method, sputtering, inkjet printing, sol-gel techniques, etc.

In some applications, the substrate can further include a backplane. The backplane can include active or passive electronics for controlling or switching power to individual pixels or light-emitting devices. Including a backplane can be useful for applications such as displays, sensors, or imagers. In particular, the backplane can be configured as an active matrix, passive matrix, fixed format, direct drive, or hybrid. The display can be configured for still images, moving images, or lighting. A display including an array of light emitting devices can provide white light, monochrome light, or color-tunable light.

In addition to the charge transport layers, a device may optionally further include one or more charge-injection layers, e.g., a hole-injection layer (either as a separate layer or as part of the hole transport layer) and/or an electron-injection layer (either as a separate layer as part of the electron transport layer). Charge injection layers comprising organic materials can be intrinsic (un-doped) or doped. A hole injecting layer can comprise PEDOT:PSS.

One or more charge blocking layers may still further optionally be included. For example, an electron blocking layer (EBL), a hole blocking layer (HBL), or an exciton blocking layer (eBL), can be introduced in the structure. A blocking layer can include, for example, 3-(4-biphenylyl)-4-phenyl-5-tert butylphenyl-1,2,4-triazole (TAZ), 3,4,5-triphenyl-1,2,4-triazole, 3,5-bis(4-tert-butylphenyl)-4-phenyl-1,2,4-triazole, bathocuproine (BCP), 4,4′,4″-tris{N-(3-methylphenyl)-N-phenylamino}triphenylamine (m-MTDATA), polyethylene dioxythiophene (PEDOT), 1,3-bis(5-(4-diphenylamino)phenyl-1,3,4-oxadiazol-2-yl)benzene, 2-(4-biphenylyl)-5-(4-tertbutylphenyl)-1,3,4-oxadiazole, 1,3-bis[5-(4-(1,1-dimethylethyl)phenyl)-1,3,4-oxadiazol-5,2-yl)benzene, 1,4-bis(5-(4-diphenylamino)phenyl-1,3,4-oxadiazol-2-yl)benzene, 1,3,5-tris[5-(4-(1,1-dimethylethyl)phenyl)-1,3,4-oxadiazol-2-yl)benzene, or 2,2′,2″-(1,3,5-Benzinetriyl)-tris(1-phenyl-1-H-benzimidazole) (TPBi).

Charge blocking layers comprising organic materials can be intrinsic (un-doped) or doped.

Charge injection layers (if any), and charge blocking layers (if any) can be deposited by spin coating, dip coating, vapor deposition, or other thin film deposition methods. See, for example, M. C. Schlamp, et al., J. Appl. Phys., 82, 5837-5842, (1997); V. Santhanam, et al., Langmuir, 19, 7881-7887, (2003); and X. Lin, et al., J. Phys. Chem. B, 105, 3353-3357, (2001), each of which is incorporated by reference in its entirety.

A device can further include a cover, coating or layer over the surface of the device opposite the substrate for protection from the environment (e.g., dust, moisture, and the like) and/or scratching or abrasion. In a further embodiment, the cover can further optionally include a lens, prismatic surface, etc. Anti-reflection, light polarizing, and/or other coatings can also optionally be included over the pattern.

Optionally, a sealing material (e.g., UV curable epoxy or other sealant) can be further added around any uncovered edges around the perimeter of the device.

A quantum dot is a nanometer sized particle that can have optical properties arising from quantum confinement. The particular composition(s), structure, and/or size of a quantum dot can be selected to achieve the desired wavelength of light to be emitted from the quantum dot upon stimulation with a particular excitation source. In essence, quantum dots may be tuned to emit light across the visible spectrum by changing their size. See C. B. Murray, C. R. Kagan, and M. G. Bawendi, Annual Review of Material Sci., 2000, 30: 545-610 hereby incorporated by reference in its entirety.

A quantum dot can have an average particle size in a range from about 1 to about 1000 nanometers (nm), and preferably in a range from about 1 to about 100 nm. In certain embodiments, quantum dots have an average particle size in a range from about 1 to about 20 nm (e.g., such as about 5, 6, 7, 8, 9, 10, 11, 12, 13, 14, 15, 16, 17, 18, 19, or 20 nm). In certain embodiments, quantum dots have an average particle size in a range from about 1 to about 10 nm. Quantum dots can have an average diameter less than about 150 Angstroms (Å). In certain embodiments, quantum dots having an average diameter in a range from about 12 to about 150 Å can be particularly desirable. However, depending upon the composition, structure, and desired emission wavelength of the quantum dot, the average diameter may be outside of these ranges.

For convenience, the size of quantum dots can be described in terms of a “diameter”. In the case of spherically shaped quantum dots, diameter is used as is commonly understood. For non-spherical quantum dots, the term diameter can typically refer to a radius of revolution (e.g., a smallest radius of revolution) in which the entire non-spherical quantum dot would fit.

Preferably, a quantum dot comprises a semiconductor nanocrystal. In certain embodiments, a semiconductor nanocrystal has an average particle size in a range from about 1 to about 20 nm, and preferably from about 1 to about 10 nm. However, depending upon the composition, structure, and desired emission wavelength of the quantum dot, the average diameter may be outside of these ranges.

A quantum dot can comprise one or more semiconductor materials.

Examples of semiconductor materials that can be included in a quantum dot (including, e.g., semiconductor nanocrystal) include, but are not limited to, a Group IV element, a Group II-VI compound, a Group II-V compound, a Group III-VI compound, a Group III-V compound, a Group IV-VI compound, a Group compound, a Group II-IV-VI compound, a Group II-IV-V compound, an alloy including any of the foregoing, and/or a mixture including any of the foregoing, including ternary and quaternary mixtures or alloys. A non-limiting list of examples include ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InP, InSb, AlAs, AlN, AlP, AlSb, TlN, TlP, TlAs, TlSb, PbO, PbS, PbSe, PbTe, Ge, Si, an alloy including any of the foregoing, and/or a mixture including any of the foregoing, including ternary and quaternary mixtures or alloys.

A quantum dot can comprise a core comprising one or more semiconductor materials and a shell comprising one or more semiconductor materials, wherein the shell is disposed over at least a portion, and preferably all, of the outer surface of the core. A quantum dot including a core and shell is also referred to as a “core/shell” structure.

Examples of semiconductor materials that can be included in a core include, but are not limited to, a Group IV element, a Group II-VI compound, a Group II-V compound, a Group III-VI compound, a Group III-V compound, a Group IV-VI compound, a Group compound, a Group II-IV-VI compound, a Group II-IV-V compound, alloys including any of the foregoing, and/or mixtures including any of the foregoing, including ternary and quaternary mixtures or alloys. Examples include, but are not limited to, ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InP, InSb, AlAs, AlN, AlP, AlSb, TlN, TlP, TlAs, TlSb, PbO, PbS, PbSe, PbTe, Ge, Si, an alloy including any of the foregoing, and/or a mixture including any of the foregoing, including ternary and quaternary mixtures or alloys.

A shell can be a semiconductor material having a composition that is the same as or different from the composition of the core. The shell can comprise an overcoat including one or more semiconductor materials on a surface of the core. Examples of semiconductor materials that can be included in a shell include, but are not limited to, a Group IV element, a Group II-VI compound, a Group II-V compound, a Group III-VI compound, a Group III-V compound, a Group IV-VI compound, a Group compound, a Group II-IV-VI compound, a Group II-IV-V compound, alloys including any of the foregoing, and/or mixtures including any of the foregoing, including ternary and quaternary mixtures or alloys. Examples include, but are not limited to, ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InP, InSb, AlAs, AlN, AlP, AlSb, TlN, TlP, TlAs, TlSb, PbO, PbS, PbSe, PbTe, Ge, Si, an alloy including any of the foregoing, and/or a mixture including any of the foregoing. For example, ZnS, ZnSe or CdS overcoatings can be grown on CdSe or CdTe semiconductor nanocrystals.

In a core/shell quantum dot, the shell or overcoating may comprise one or more layers. The overcoating can comprise at least one semiconductor material which is the same as or different from the composition of the core. Preferably, the overcoating has a thickness from about one to about ten monolayers. An overcoating can also have a thickness greater than ten monolayers. In certain embodiments, more than one overcoating can be included on a core.

In certain embodiments, the surrounding “shell” material can have a band gap greater than the band gap of the core material. In certain other embodiments, the surrounding shell material can have a band gap less than the band gap of the core material.

In certain embodiments, the shell can be chosen so as to have an atomic spacing close to that of the “core” substrate. In certain other embodiments, the shell and core materials can have the same crystal structure.

Examples of quantum dot (e.g., semiconductor nanocrystal) (core)shell materials include, without limitation: red (e.g., (CdSe)CdZnS (core)shell), green (e.g., (CdZnSe)CdZnS (core)shell, etc.), and blue (e.g., (CdS)CdZnS (core)shell.

Quantum dots can have various shapes, including, but not limited to, sphere, rod, disk, other shapes, and mixtures of various shaped particles.

One example of a method of manufacturing a quantum dot (including, for example, but not limited to, a semiconductor nanocrystal) is a colloidal growth process. Colloidal growth can occur by injection an M donor and an X donor into a hot coordinating solvent. M can comprise, for example, one or more metals including, but not limited to, for example, cadmium, zinc, magnesium, mercury, aluminum, gallium, indium, thallium, or mixtures thereof. X can comprise, for example, one or more chalcogens or pnictogens, including, but not limited to, oxygen, sulfur, selenium, tellurium, nitrogen, phosphorus, arsenic, antimony, or mixtures thereof.

An M donor can be an inorganic compound, an organometallic compound, or elemental metal. For example, an M donor can comprise cadmium, zinc, magnesium, mercury, aluminum, gallium, indium or thallium, and the X donor can comprise a compound capable of reacting with the M donor to form a material with the general formula MX.

An X donor can comprise a chalcogenide donor or a pnictide donor, such as a phosphine chalcogenide, a bis(silyl)chalcogenide, dioxygen, an ammonium salt, or a tris(silyl)pnictide. Suitable X donors include, for example, but are not limited to, dioxygen, bis(trimethylsilyl)selenide ((TMS)₂Se), trialkyl phosphine selenides such as (tri-noctylphosphine) selenide (TOPSe) or (tri-n-butylphosphine) selenide (TBPSe), trialkyl phosphine tellurides such as (tri-n-octylphosphine) telluride (TOPTe) or hexapropylphosphorustriamide telluride (HPPTTe), bis(trimethylsilyl)telluride ((TMS)₂Te), bis(trimethylsilyl)sulfide ((TMS)₂S), a trialkyl phosphine sulfide such as (tri-noctylphosphine) sulfide (TOPS), an ammonium salt such as an ammonium halide (e.g., NH₄Cl), tris(trimethylsilyl)phosphide ((TMS)₃P), tris(trimethylsilyl)arsenide ((TMS)₃As), or tris(trimethylsilyl)antimonide ((TMS)₃Sb). In certain embodiments, the M donor and the X donor can be moieties within the same molecule.

One example of a preferred method for preparing monodisperse quantum dots comprises pyrolysis of organometallic reagents, such as dimethyl cadmium, injected into a hot, coordinating solvent. This permits discrete nucleation and results in the controlled growth of macroscopic quantities of quantum dots. The injection produces a nucleus that can be grown in a controlled manner to form a quantum dot. The reaction mixture can be gently heated to grow and anneal the quantum dot. Both the average size and the size distribution of the quantum dots in a sample are dependent on the growth temperature. The growth temperature for maintaining steady growth increases with increasing average crystal size. Resulting quantum dots are members of a population of quantum dots. As a result of the discrete nucleation and controlled growth, the population of quantum dots that can be obtained has a narrow, monodisperse distribution of diameters. The monodisperse distribution of diameters can also be referred to as a size. Preferably, a monodisperse population of particles includes a population of particles wherein at least about 60% of the particles in the population fall within a specified particle size range. A population of monodisperse particles preferably deviate less than 15% rms (root-mean-square) in diameter and more preferably less than 10% rms and most preferably less than 5%.

The process of controlled growth and annealing of the quantum dots in the coordinating solvent that follows nucleation can also result in uniform surface derivatization and regular core structures. As the size distribution sharpens, the temperature can be raised to maintain steady growth. For example, by adding more M donor or X donor, the growth period can be shortened. A coordinating solvent can help control the growth of the quantum dot. A coordinating solvent is a compound having a donor lone pair that, for example, a lone electron pair available to coordinate to a surface of the growing quantum dot (including, e.g., a semiconductor nanocrystal). Solvent coordination can stabilize the growing quantum dot. Examples of coordinating solvents include alkyl phosphines, alkyl phosphine oxides, alkyl phosphonic acids, or alkyl phosphinic acids, however, other coordinating solvents, such as pyridines, furans, and amines may also be suitable for the quantum dot (e.g., semiconductor nanocrystal) production. Additional examples of suitable coordinating solvents include pyridine, tri-n-octyl phosphine (TOP), tri-n-octyl phosphine oxide (TOPO) and trishydroxylpropylphosphine (tHPP), tributylphosphine, tri(dodecyl)phosphine, dibutyl-phosphite, tributyl phosphite, trioctadecyl phosphite, trilauryl phosphite, tris(tridecyl)phosphite, triisodecyl phosphite, bis(2-ethylhexyl)phosphate, tris(tridecyl)phosphate, hexadecylamine, oleylamine, octadecylamine, bis(2-ethylhexyl)amine, octylamine, dioctylamine, trioctylamine, dodecylamine/laurylamine, didodecylamine tridodecylamine, hexadecylamine, dioctadecylamine, trioctadecylamine, phenylphosphonic acid, hexylphosphonic acid, tetradecylphosphonic acid, octylphosphonic acid, octadecylphosphonic acid, propylenediphosphonic acid, phenylphosphonic acid, aminohexylphosphonic acid, dioctyl ether, diphenyl ether, methyl myristate, octyl octanoate, and hexyl octanoate. In certain embodiments, technical grade TOPO can be used.

In certain embodiments, quantum dots can alternatively be prepared with use of non-coordinating solvent(s).

Size distribution during the growth stage of the reaction can be estimated by monitoring the absorption or emission line widths of the particles. Modification of the reaction temperature in response to changes in the absorption spectrum of the particles allows the maintenance of a sharp particle size distribution during growth. Reactants can be added to the nucleation solution during crystal growth to grow larger crystals. For example, for CdSe and CdTe, by stopping growth at a particular semiconductor nanocrystal average diameter and choosing the proper composition of the semiconducting material, the emission spectra of the semiconductor nanocrystals can be tuned continuously over the wavelength range of 300 nm to 5 microns, or from 400 nm to 800 nm.

The particle size distribution of the quantum dots (including, e.g., semiconductor nanocrystals) can be further refined by size selective precipitation with a poor solvent for the quantum dots, such as methanol/butanol. For example, quantum dots can be dispersed in a solution of 10% butanol in hexane. Methanol can be added dropwise to this stirring solution until opalescence persists. Separation of supernatant and flocculate by centrifugation produces a precipitate enriched with the largest crystallites in the sample. This procedure can be repeated until no further sharpening of the optical absorption spectrum is noted. Size-selective precipitation can be carried out in a variety of solvent/nonsolvent pairs, including pyridine/hexane and chloroform/methanol. The size-selected quantum dot (e.g., semiconductor nanocrystal) population preferably has no more than a 15% rms deviation from mean diameter, more preferably 10% rms deviation or less, and most preferably 5% rms deviation or less.

An example of an overcoating process is described, for example, in U.S. Pat. No. 6,322,901. By adjusting the temperature of the reaction mixture during overcoating and monitoring the absorption spectrum of the core, overcoated materials having high emission quantum efficiencies and narrow size distributions can be obtained.

The narrow size distribution of the quantum dots (including, e.g., semiconductor nanocrystals) allows the possibility of light emission in narrow spectral widths. Monodisperse semiconductor nanocrystals have been described in detail in Murray et al. (J. Am. Chem. Soc., 115:8706 (1993). The foregoing is hereby incorporated herein by reference in its entirety.

The emission from a quantum dot capable of emitting light can be a narrow Gaussian emission band that can be tuned through the complete wavelength range of the ultraviolet, visible, or infra-red regions of the spectrum by varying the size of the quantum dot, the composition of the quantum dot, or both. For example, a semiconductor nanocrystal comprising CdSe can be tuned in the visible region; a semiconductor nanocrystal comprising InAs can be tuned in the infra-red region. The narrow size distribution of a population of quantum dots capable of emitting light can result in emission of light in a narrow spectral range. The population can be monodisperse preferably exhibits less than a 15% rms (root-mean-square) deviation in diameter of such quantum dots, more preferably less than 10%, most preferably less than 5%. Spectral emissions in a narrow range of no greater than about 75 nm, preferably no greater than about 60 nm, more preferably no greater than about 40 nm, and most preferably no greater than about 30 nm full width at half max (FWHM) for such quantum dots that emit in the visible can be observed. IR-emitting quantum dots can have a FWHM of no greater than 150 nm, or no greater than 100 nm. Expressed in terms of the energy of the emission, the emission can have a FWHM of no greater than 0.05 eV, or no greater than 0.03 eV. The breadth of the emission decreases as the dispersity of the light-emitting quantum dot diameters decreases.

Quantum dots can have emission quantum efficiencies such as greater than 10%, 20%, 30%, 40%, 50%, 60%, 70%, 80%, or 90%.

The narrow FWHM of quantum dots can result in saturated color emission. The broadly tunable, saturated color emission over the entire visible spectrum of a single material system is unmatched by any class of organic chromophores (see, for example, Dabbousi et al., J. Phys. Chem. 101, 9463 (1997), which is incorporated by reference in its entirety). A monodisperse population of quantum dots will emit light spanning a narrow range of wavelengths.

Other materials, techniques, methods, applications, and information that may be useful with the present invention are described in, U.S. patent application Ser. No. 11/354,185, filed 15 Feb. 2006, International Application No. PCT/US2009/002123 filed 3 Apr. 2009 of QD Vision, Inc. for “Light-Emitting Device Including Quantum Dots”, International Application No. PCT/US2010/51867 of QD Vision, Inc., filed 7 Oct. 2010, International Application No. PCT/US2010/56397 of QD Vision, Inc., filed 11 Nov. 2010, International Application No. PCT/US2007/008873, filed Apr. 9, 2007, of Coe-Sullivan et al., for “Composition Including Material, Methods Of Depositing Material, Articles Including Same And Systems For Depositing Material”; International Application No. PCT/US2008/10651, of Breen, et al., for “Functionalized Nanoparticles And Method”, filed 12 Sep. 2008, International Application No. PCT/US2007/013152, filed Jun. 4, 2007, of Coe-Sullivan, et al., for “Light-Emitting Devices And Displays With Improved Performance”; International Application No. PCT/US2007/003677, filed Feb. 14, 2007, of Bulovic, et al., for “Solid State Lighting Devices Including Semiconductor Nanocrystals & Methods”. The disclosures of each of the foregoing listed patent documents are hereby incorporated herein by reference in their entireties.

As used herein, the singular forms “a”, “an” and “the” include plural unless the context clearly dictates otherwise. Thus, for example, reference to an emissive material includes reference to one or more of such materials.

As used herein, “top”, “bottom”, “over”, and “under” are relative positional terms, based upon a location from a reference point. Where, e.g., a layer is described as disposed or deposited “over” another layer, component, or substrate there may be other layers, components, etc. between the layer and the other layer, component or substrate. As used herein, “cover” is also a relative position term, based upon a location from a reference point. For example, where a first material is described as covering a second material, the first material is disposed over, but not necessarily in contact with the second material.

The entire contents of all patent publications and other publications cited in this disclosure are hereby incorporated herein by reference in their entirety. Further, when an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

Other embodiments of the present invention will be apparent to those skilled in the art from consideration of the present specification and practice of the present invention disclosed herein. It is intended that the present specification and examples be considered as exemplary only with a true scope and spirit of the invention being indicated by the following claims and equivalents thereof.

1. A method for preparing a device, the method comprising:
forming a first device layer over a first electrode, the layer comprising a metal oxide formed from a sol-gel composition that does not generate acidic by-products, and
forming a second electrode over the first device layer,
wherein the method further includes forming a layer comprising quantum dots over the first electrode before or after formation of the first device layer.

2. A method in accordance with claim 1 wherein the sol gel composition comprises a metal oxide precursor comprising a metal hydroxide, a metal alkoxide, a metal alkylalkoxide, or a mixture thereof.

3. A method in accordance with claim 1 wherein the metal oxide first device layer comprises zinc oxide, titanium oxide, or mixtures thereof.

4. A method in accordance with claim 1 wherein the first device layer comprises a charge transport layer.

5. A method in accordance with claim 1 wherein the method further comprises forming a second device layer before or after formation of the layer comprising quantum dots, such that the layer comprising quantum dots is disposed between the first and second device layers.

6. A method in accordance with claim 1 wherein the first electrode is disposed on a substrate.

7. A method in accordance with claim 1 wherein the device comprises a light-emitting device.

8. A method in accordance with claim 1, wherein the sol-gel composition is processed at a temperature less than about 200° C.

9. A method in accordance with claim 1 the layer comprising quantum dots is deposited before formation of the first device layer.

10. A method in accordance with claim 1 the layer comprising quantum dots is deposited after formation of the first device layer.

11. A method in accordance with claim 1 wherein the sol-gel composition comprises a metal oxide precursor.

12. A device prepared in accordance with the method of claim 1.

13. A device in accordance with claim 12 wherein the device comprises a light-emitting device.

14. A device comprising a first device layer formed over a first electrode, the first device layer comprising a metal oxide formed by sol-gel processing that does not include acidic by-products, a second electrode over the first device layer, and a layer comprising quantum dots disposed between the first device layer and one of the two electrodes.

15. A device in accordance with claim 14 wherein the metal oxide comprises zinc oxide, titanium oxide, or mixtures thereof.

16. A device in accordance with claim 14 wherein the first device layer comprises a charge transport layer.

17. A device in accordance with claim 14 wherein the device further includes a second device layer, wherein the layer comprising quantum dots is disposed between the first and second device layers.

18. A device in accordance with claim 14 wherein the first electrode is disposed on a substrate.

19. A device in accordance with claim 14 wherein the device comprises a light-emitting device.

20. (canceled)
